(19) United States
(12) Patent Application Publication
(10) Pub. No.: US 2016/0118241 A1
(43) Pub. Date: Apr. 28, 2016

(54) SUBSTRATE TREATING APPARATUS AND SUBSTRATE CLEANING METHOD

(71) Applicant: Semes Co., Ltd., Cheonan-si (KR)

(72) Inventors: Seong Soo LEE, Seoul (KR); Keunje JO, Seoul (KR); Soon Kab KWON, Gimhae-si (KR); Jong Han KIM, Asan-si (KR); Bok Kyu LEE, Cheonan-si (KR); Yoon-Jong JU, Cheonan-si (KR)

(21) Appl. No.: 14/879,389

(22) Filed: Oct. 9, 2015

(30) Foreign Application Priority Data
Oct. 24, 2014 (KR) 10-2014-0145403

(51) Int. Cl. H01L 21/02; B08B 3/10; B08B 3/02; H01L 21/67; H01L 21/687

(52) U.S. Cl. CPC H01L 21/02057; H01L 21/67051; H01L 21/68764; B08B 3/024; B08B 3/102

(57) ABSTRACT

Disclosed is a substrate treating apparatus. The substrate treating apparatus includes a housing defining a space for treating a substrate therein, a spin head supporting and rotating the substrate in the housing, a spray unit including a first nozzle member for spraying a first treating solution on the substrate placed on the spin head, and a controller controlling the spray unit. The controller sprays the first treating solution while moving the first nozzle member between edge and center regions of the substrate and above the substrate. The controller differently adjusts a first height at which the first treating solution is sprayed on the edge region of the substrate and a second height at which the first treating solution is sprayed on the center region of the substrate.

### CROSS-REFERENCE TO RELATED APPLICATION

A claim for priority under 35 U.S.C. §119 is made to Korean Patent Application No. 10-2014-0145403 filed Oct. 24, 2014, in the Korean Intellectual Property Office, the entire contents of which are hereby incorporated by reference.

### BACKGROUND

Embodiments of the inventive concepts described herein relate to a substrate treating apparatus and a substrate cleaning method using the same.

Various processes such as photolithography, etching, ashing, ion implantation, and film deposition are performed on a substrate so as to manufacture a semiconductor device or a liquid crystal display. A substrate cleaning process for removing various contamination materials and particles attached to a substrate surface may be performed before and after each unit process for fabricating a semiconductor device.

Various methods such as spraying a chemical, a treating solution including a gas, or a treating solution with a vibration may be used as a cleaning process to remove various contamination materials and particles remaining on the substrate surface.

### SUMMARY

Embodiments of the inventive concepts provide a substrate treating apparatus capable of improving cleaning efficiency.

Embodiments of the inventive concepts provide a substrate treating apparatus.

One aspect of embodiments of the inventive concept is directed to provide a substrate treating apparatus. The substrate treating apparatus includes a housing defining a space for treating a substrate therein, a spin head supporting and rotating the substrate in the housing, a spray unit including a first nozzle member for spraying a first treating solution on the substrate placed on the spin head, and a controller controlling the spray unit, wherein the controller sprays the first treating solution while moving the first nozzle member between edge and center regions of the substrate and above the substrate, and wherein the controller differently adjusts a first height at which the first treating solution is sprayed on the edge region of the substrate and a second height at which the first treating solution is sprayed on the center region of the substrate.

The second height may be higher than the first height.

The controller may control the first nozzle member such that a height of the first nozzle member is progressively increased as the first nozzle member moves from the edge region of the substrate to the center region thereof.

The controller may control the first nozzle member such that a height of the first nozzle member is continuously increased as the first nozzle member moves from the edge region of the substrate to the center region thereof.

The first nozzle member may include a body including an injection flow path and a first discharge hole therein, the first treating solution flowing through the injection flow path and the first discharge hole connected with the injection flow path and spraying the first treating solution on the substrate, and a vibrator installed in the body and providing a vibration to the first treating solution flowing into the injection flow path.

The first nozzle member may include a body including an injection flow path and first micro-holes therein, the first treating solution flowing through the injection flow path and the first micro-holes connected with the injection flow path and spraying the first treating solution on the substrate.

The first nozzle member may include a body including an injection flow path and a first discharge hole therein, the first treating solution flowing through the injection flow path and the first discharge hole connected with the injection flow path and spraying the first treating solution on the substrate, and a gas supply unit installed in the body and spraying a gas together with the first treating solution sprayed through the first discharge hole.

The injection flow path may include a first region and a second region each having a ring shape when viewed from the top, and a radius of the first region is greater than that of the second region.

When viewed from the top, the first discharge holes of the first region may be provided in a line along the first region, and the first discharge holes of the second region are provided in two lines along the second region.

The inventive concept, however, may be embodied in various different forms, and should not be construed as being limited only to the illustrated embodiments. Embodiments of the inventive concept are provided to illustrate more fully the scope of the inventive concept to those skilled in the art.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a top plan view schematically illustrating a substrate treating apparatus;

FIG. 2 is a cross-sectional view illustrating a substrate treating apparatus of FIG. 1;

FIG. 3 is a cross-sectional view illustrating a first nozzle member of FIG. 2;

FIG. 4 is a bottom view illustrating a first nozzle member of FIG. 3;

FIG. 5 is a diagram illustrating a conventional substrate cleaning method;

FIG. 6 is a diagram illustrating a region where a first treating solution is supplied when the first treating solution is sprayed using a substrate cleaning method of FIG. 5;

FIG. 7 is a diagram illustrating a substrate cleaning method for supplying a first treating solution on a substrate using a first nozzle member according to an embodiment of the inventive concept;

FIG. 8 is a diagram illustrating a substrate cleaning method for supplying a first treating solution on a substrate using a first nozzle member according to another embodiment of the inventive concept;

FIG. 9 is a diagram illustrating a surface velocity at which a first treating solution reaches a substrate, varied according to a spray height of the first nozzle member;

FIG. 10 is a diagram illustrating a first nozzle member according to other embodiment of the inventive concept; and

FIG. 11 is a diagram illustrating a first nozzle member according to another embodiment of the inventive concept.

### DETAILED DESCRIPTION

Embodiments will be described in detail with reference to the accompanying drawings. The inventive concept, however, may be embodied in various different forms, and should not be construed as being limited only to the illustrated embodiments. Embodiments of the inventive concept are provided to illustrate more fully the scope of the inventive concept to those skilled in the art. Therefore, the shapes of the components in the drawings may be exaggerated to emphasize a more clear description.

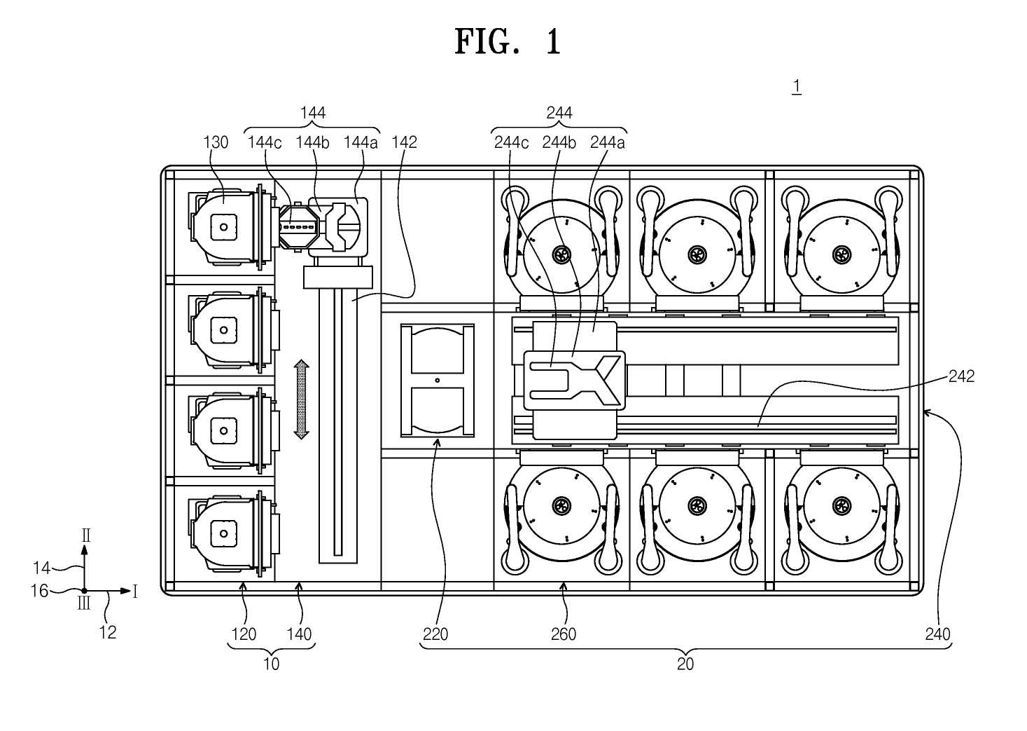

Below, an example of the inventive concept will be described with reference to FIGS. 1 to 11.

FIG. 1 is a top plan view schematically illustrating a substrate treating apparatus according to an embodiment of the inventive concept. Referring to FIG. 1, a substrate treating apparatus 1 may have an index module 10 and a process treating module 20. The index module 100 may contain a load port 120 and a transfer frame 140. The load port 120, the transfer frame 140, and the process treating module 20 may be arranged in a line. Below, a direction where the load port 120, the transfer frame 140, and the process treating module 20 are arranged may be referred to as “first direction” 12. When viewed from the top, a direction perpendicular to the first direction 12 may be referred to as “second direction” 14, and a direction perpendicular to a plane defined by the first direction 12 and the second direction 14 may be referred to as “third direction” 16.

A carrier 130 where a substrate W is received may be safely put on the load port 120. The load port 120 may be in plurality, and the plurality of load ports 120 may be arranged in a line along the second direction 14. The number of load ports 120 may increase or decrease according to conditions such as process efficiency, footprint, and the like in the process treating module 20. A plurality of slots (not illustrated) may be formed in the carrier 130 so as to receive the substrates W in a state where they are placed in a horizontal position on the ground surface. A Front Opening Unified Pod (FOUP) may be used as the carrier 130.

The process treating module 20 may contain a buffer unit 220, a transfer chamber 240, and process chambers 260. The transfer chamber 240 may be arranged such that its length direction is parallel with the first direction 12. The process chambers 260 may be arranged at opposite sides of the transfer chamber 240 along the second direction 14. The process chambers 260 may be arranged at one side and the other side of the transfer chamber 240 so as to be arranged symmetrically with respect to the transfer chamber 240. The plurality of process chambers 260 may be provided at one side of the transfer chamber 240. A portion of the process chambers 260 may be arranged along a length direction of the transfer chamber 240. Furthermore, a portion of the process chambers 260 may be arranged to be stacked. That is, the process chambers 260 may be arranged in an A-by-B matrix at the one side of the transfer chamber 240. In this case, “A” may indicate the number of process chambers 260 arranged in a line along the first direction 12, and “B” may indicate the number of process chambers 260 arranged in line along the third direction 16. When four or six process chambers 260 are arranged at the one side of the transfer chamber 240, the process chambers 260 may be arranged in a 2-by-2 or 3-by-2 matrix. The number of process chambers 260 may increase or decrease. Unlikely, the process chambers 260 may be provided at any one side of the transfer chamber 240. In addition, the process chambers 260 may be arranged at one side and opposite sides of the transfer chamber 240 to form a single layer.

The buffer unit 220 may be disposed between the transfer frame 140 and the transfer chamber 240. The buffer unit 220 may provide a space where a substrate W stays before transferred between the transfer chamber 240 and the transfer frame 140. A slot(s) (not illustrated) where a substrate W is placed may be provided in the buffer unit 220. A plurality of slots may be provided to be spaced apart from each other along the third direction 16. The buffer unit 220 may have an opened surface that faces the transfer frame 140 and an opened surface that faces the transfer chamber 240.

The transfer frame 140 may transfer a wafer W between the buffer unit 220 and the carrier 130 safely put on the load port 120. An index rail 142 and an index robot 144 may be provided at the transfer frame 140. The index rail 142 may be provided such that its length direction is parallel with the second direction 14. The index robot 144 may be mounted on the index rail 142 and may move in a straight line toward the second direction 14 along the index rail 142. The index robot 144 may contain a base 144a, a body 144b, and an index arm 144c. The base 144a may be installed to be movable along the index rail 142. The body 144b may be joined to the base 144a. The body 144b may be provided to be movable on the base 144a along the third direction 16. Furthermore, the body 144b may be provided to be rotatable on the base 144a. The index arm 144c may be joined to the body 144b such that it is forward and backward movable with respect to the body 144b. The index arm 144c may be in plurality, and the plurality of index arms 144c may be driven independently of each other. The index arms 144c may be arranged to be stacked on each other under the condition that index arms 144c are spaced apart from each other along the third direction 16. A portion of the index arms 144c may be used to transfer a substrate W from the process treating module 20 to the carrier 130, and a portion of remaining index arms 144c may be used to transfer the substrate W from the process treating module 20 to the carrier 130, thereby preventing particles, generated from a substrate W not experiencing process treating when the substrate W is carried into or taken out of by the index robot 144, from being attached to the substrate W.

The transfer chamber 240 may transfer a substrate W between the buffer unit 220 and the process chamber 260 and between the process chambers 260. A guide rail 242 and a main robot 244 may be provided at the transfer chamber 240. The guide rail 242 may be arranged such that its length direction is parallel with the first direction 12. The main robot 244 may be installed on the guide rail 242 and may move in a straight line along the first direction 12 on the guide rail 242. The main robot 244 may contain a base 244a, a body 244b, and a main arm 244c. The base 244a may be installed to be movable along the guide rail 242. The body 244b may be joined to the base 244a. The body 244b may be provided to be movable on the base 244a along the third direction 16. Furthermore, the body 244b may be provided to be rotatable on the base 244a. The main arm 244c may be joined to the body 244b such that it is forward and backward movable with respect to the body 144b. The main arm 244c may be in plurality, and the plurality of main arms 244c may be driven independently of each other. The main arms 244c may be arranged to be stacked on each other in a state where the main arms 244c are spaced apart from each other along the third direction 16.

A substrate treating apparatus 300 performing a cleaning process for cleaning a substrate W may be provided in the process chamber 260. The substrate treating apparatus 300 may have different structures according to types of cleaning processes. In contrast, the substrate treating apparatuses 300 of the process chambers 260 may have the same structure. Selectively, the process chambers 260 may be divided into a plurality of groups. The substrate treating apparatuses 300 in the same groups may have the same structure, and the substrate treating apparatuses 300 in different groups may have different structures.

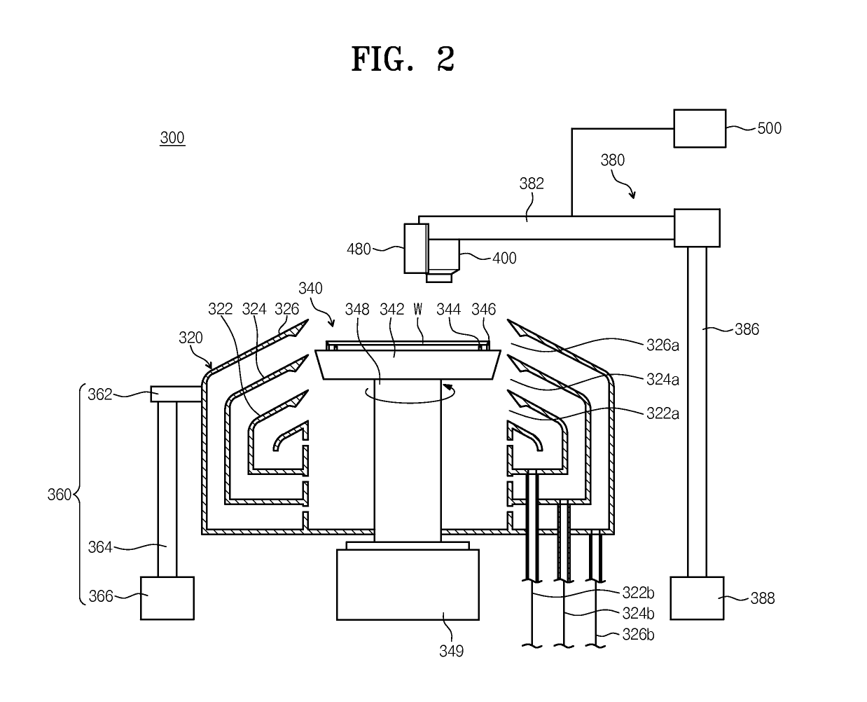

FIG. 2 is a cross-sectional view illustrating a substrate treating apparatus of FIG. 1. Referring to FIG. 2, the substrate treating apparatus 300 may include a housing 320, a spin head 340, an elevation unit 360, a spray unit 380, and a controller 500. The housing 320 may contain a space where the substrate treating process is performed and an upper end portion of the housing 320 may be opened. The housing 320 may contain an internal collection barrel 322 and an external collection barrel 326. The internal and external collection barrels 322 and 326 may collect different treating solutions among treating solutions used in a process, respectively. The internal collection barrel 322 may be provided in the form of a ring surrounding the spin head 340, and the external collection barrel 326 may be provided in the form of a ring surrounding the internal collection barrel 322. An internal space 322a of the internal collection barrel 322 and a space 326a between the internal collection barrel 322 and the external collection barrel 326 may serve as inlets that allow the treating solutions to flow into the internal collection barrel 322 and the external collection barrel 326, respectively. Collection lines 322b and 326b which extend vertically and downwardly toward the bottom may be connected to the respective collection barrels 322 and 326. The collection lines 322b and 326b may discharge treating solutions collected by the collection barrels 322 and 326. The discharged treating solutions may be recycled through an external treating solution recycling system (not illustrated).

The spin head 340 may support and rotate a substrate W during a process. The spin head 340 may include a body 342, a support pin 344, a chuck pin 346, and a support shaft 348. The body 342 may have an upper surface provided in the form of a circle when viewed from the top. The support shaft 348 rotated by a motor 349 may be fixedly mounted on a lower surface of the body 342.

The support pin 344 may be provided in plurality. The support pins 344 may be disposed to be spaced apart by a predetermined gap from an edge of the upper surface of the body 342 and may protrude upwardly from the body 342. The support pins 344 may be disposed to have the form of a ring as a whole through a combination thereof. The support pins 344 may support an edge of a rear surface of the substrate W to allow the substrate W to be spaced apart by a predetermined distance from the upper surface of the body 342.

The chunk pin 346 may be provided in plurality. The chuck pins 346 may be disposed such that it is further away from the center of the body 342 than the support pin 344. The chuck pin 346 may be provided to protrude upwardly from the body 342. The chuck pin 346 may support a side portion of the substrate W to prevent the substrate W from deviating from a given position to a lateral direction when the spin head 340 rotates. The chuck pin 346 may be provided to move in a straight line between a waiting position and a support position along a radius direction of the body 342. The waiting position may be a position such that it is further away from the center of the body 342 than the support pin 344. When the substrate W is loaded on or unloaded from the body 342, the chuck pin 346 may be placed at the waiting position; when a substrate treating process is performed, the chuck pin 346 may be placed at the support position. The chuck pin 346 may be contacted with a side portion of the substrate W at the support position.

The elevation unit 360 may upwardly or downwardly move the housing 320 in a straight line. A height relative to the spin head 340 may be changed as the housing 320 moves upwardly or downwardly. The elevation unit 360 may include a bracket 362, a moving shaft 364, and a driver 366. The bracket 362 may be fixedly installed on an outer wall of the housing 320 and the moving shaft 364 which moves upwardly or downwardly by the driver 366 may be fixedly jointed with the bracket 362. When the substrate W is loaded on or lifted from the spin head 340, the housing 320 may descend such that the spin head 340 protrudes upwardly from an upper portion of the housing 320. Furthermore, when the process is performed, a height of the housing 320 may be adjusted such that the treating solution flows into a predetermined collection barrel 360 depending on a type of the treating solution supplied to the substrate W. Selectively, the elevation unit 360 may move the spin head 340 upwardly or downwardly.

The spray unit 380 may spray the treating solution on the substrate W. The spray unit 380 may be provided in plurality to spray various kinds of treating solutions or to spray the same kind of treating solutions in various ways. The spray unit 380 may include a support shaft 386, a nozzle arm 382, a first nozzle member 400, a cleaning member, and a second nozzle member 480. The support shaft 386 may be disposed at one side of the housing 320. The support shaft 386 may have a rod form where its length direction is a vertical direction. The support shaft 386 may be rotated, ascended and descended by a driver member 388. In contrast, the support shaft 386 may be moved and ascended and descended in a straight line along a horizontal direction by the driver member 388. The nozzle arm 382 may be fixedly jointed at a top end of the support shaft 386. The nozzle arm 382 may support a first nozzle member 400 and a second nozzle member 480. The first nozzle member 400 and the second nozzle member 480 may be disposed at an end portion of the nozzle arm 382. For example, the second nozzle member 480 may be located closer to the end portion relative to the first nozzle member 400. A cleaning member may clean the first nozzle member 400. The cleaning member may be provided at one side in the housing 320. When a first treating solution is discharged on the substrate through the first nozzle member 400, the controller 500 may place the first nozzle member 400 at a discharging position above the substrate. In contrast, when the discharging of the first treating solution is completed, the controller 500 may place the first nozzle member 400 at a cleaning position in a liquid bath.

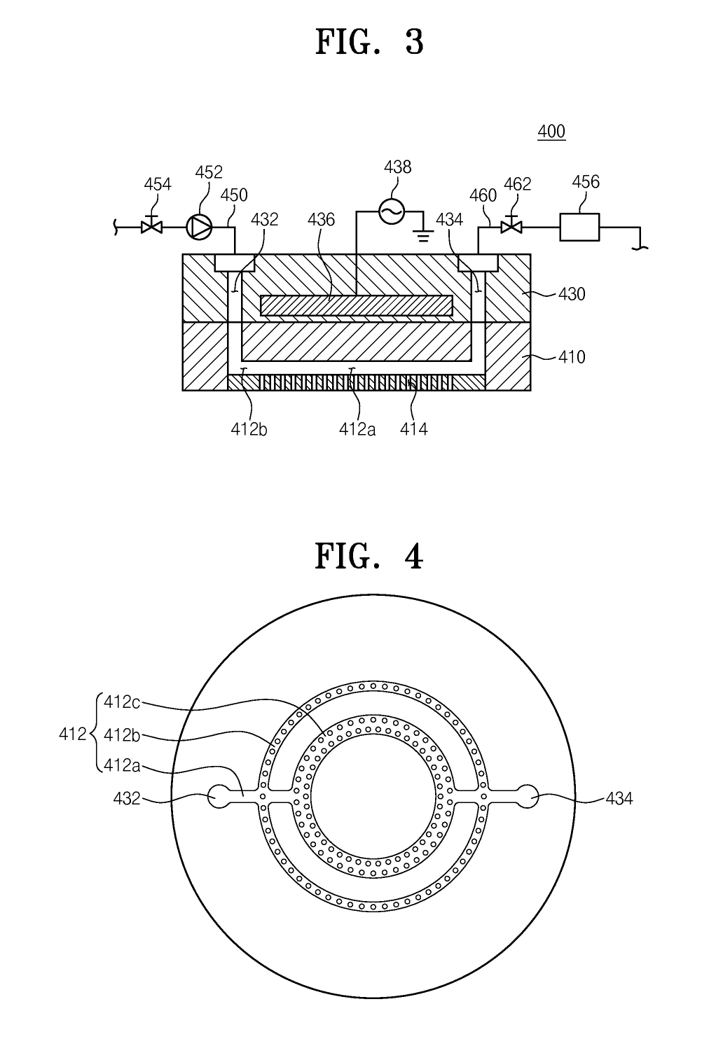

FIG. 3 is a cross-sectional view illustrating a first nozzle member 400 according to an embodiment of the inventive concept. FIG. 4 is a bottom view illustrating the first nozzle member 400 of FIG. 3. The first nozzle member 400 may spray the first treating solution in a spray manner. When viewed from the top, the first nozzle member 400 may be provided in the form of a ring. Referring to FIGS. 3 and 4, the first nozzle member 400 may spray the first treating solution in an inkjet manner. The first nozzle member 400 may include a body 410 and 430, a vibrator 436, a treating solution supply line 450, and a treating solution collection line 460. The body 410 and 430 may contain a lower plate 410 and an upper plate 430. The lower plate 410 may have a cylinder form. An injection flow path 412 through which the first treating solution flows may be formed in the lower plate 410. A plurality of first discharge holes 414 may be formed at a lower surface of the lower plate 410 to spray the first treating solution, and each of the first discharge holes 414 may be connected with the injection flow path 412. The first discharge holes 414 may be microscopic holes. The injection flow path 412 may include a first region 412b, a second region 412c, and a third region 412a. When viewed from the top, the first region 412b and the second region 412c may be provided in the form of a ring. In this case, a radius of the first region 412b may be greater than that of the second region 412c. The first discharge holes 414 of the first region 412b may be provided in a line along the first region 412b. The first discharge holes 414 of the second region 412c may be provided in tow lines along the second region 412c. The third region 412a may connect the first region 412b and the second region 412c to an inflow path 432. The third region 412a may connect the first region 412b and the second region 412c to a collection flow path 434. For example, as illustrated in FIG. 4, the third region 412a may connect the inflow path 432 or the collection flow path 434 to the third region 412a. The upper plate 430 may be provided in the form of a cylinder having the same diameter as the lower plate 410. The upper plate 430 may be fixedly jointed on a top surface of the lower plate 410. The inflow path 432 and the collection flow path 434 may be formed at an inside of the upper plate 430. The inflow path 432 and the collection flow path 434 may be provided to pass through the second region 412b of the injection flow path 412. The inflow path 432 may function as an inlet into which the first treating solution flows, and the collection flow path 434 may function as an outlet through which the first treating solution is collected from the injection flow path 412. The inflow path 432 and the collection flow path 434 may be disposed to face each other with the first nozzle member 400 as the center

The vibrator 436 may be placed in the upper plate 430. When viewed from the top, the vibrator 436 may be provided to have a ring shape. For example, the vibrator 436 may be provided to have the same diameter as the first region 412b. Selectively, the diameter of the vibrator 436 may be greater than that of the first region 412b and may be smaller than that of the upper plate 430. The vibrator 436 may be electrically connected to a power 438 placed at an outside. The vibrator 436 may provide a vibration to the first treating solution to be sprayed and may adjust a particle size and a flow velocity of the first treating solution. For example, the first treating solution may be electrolytic ionized water. The first treating solution may include any one of hydrogen water, oxygen water, and ozone water or all thereof. Selectively, the first treating solution may be pure water.

A treating solution supply line 450 may provide the first treating solution to the inflow path 432, and a treating solution collection line 460 may collect the first treating solution from the collection flow path 434. The treating solution supply line 450 may be connected to the inflow path 432 and the treating solution collection line 460 may be connected to the collection flow path 434. A pump 452 and a supply valve 454 may be installed on the treating solution supply line 450. A collection valve 462 may be installed on the treating solution collection line 460. The pump 452 may pressurize the first treating solution supplied from the treating solution supply line 450 into the inflow path 432. The supply valve 454 may open and close the treating solution supply line 450. According to an example, the collection valve 462 may open the treating collection line 460 before a process, and thus, the first treating solution may collect the first treating solution via the treating solution collection line 460 and may not be injected via a first injection hole 414. In contrast, the collection valve 462 may close the treating collection line 460 during a process. In this case, since the first treating solution may be filled in the injection flow path 412, an internal pressure of the injection flow path 412 may be increased. When a voltage is applied to the vibrator 436, the first treating solution may be injected via first injection hole 414.

Referring again to FIG. 2, the second nozzle member 480 may provide a second treating solution on the substrate. The second nozzle member 480 may supply the second treating solution simultaneously when the first nozzle member 400 supplies the first treating solution. In this case, the second nozzle member 480 may supply the second treating solution ahead before the first nozzle member 400 starts supplying the first treating solution. For example, the second nozzle member 480 may inject the second treating solution in a dropping manner. The second nozzle member 480 may be provided to surround a part of the first nozzle member 400. The second nozzle member 480 may be more adjacent to one end of the nozzle arm 382 than the first nozzle member 400. The second nozzle member 480 may have a second discharge hole vertically discharging the second treating solution on the substrate. When viewed from the top, the second nozzle member 480 may be provided in the form of an arc surrounding the first nozzle member 400. A straight-line distance from one end of the second nozzle member 480 to the other end thereof may be greater than a diameter of the first nozzle member 400. In this case, the first nozzle member 400 and the second nozzle member 480 may have the same center. The second treating solution may be provided as a protective liquid. For example, the second treating solution may be a solution including ammonia and hydrogen peroxide. The second treating solution may form a liquid film on the substrate W and the liquid film may relax influence of the treating solution on the substrate W. Accordingly, it may be possible to prevent a pattern on the substrate W from falling due to the second treating solution. The second treating solution may be pure water. The second discharge hole may be provided in the form of a single slit. Selectively, the second discharge hole may include in a plurality of circular discharge holes. The second nozzle member 480 may spray the second treating solution into a region adjacent to a region in which the first treating solution is sprayed on the substrate W. A region where the second treating solution sprayed may be closer to a center region of the substrate W than that where the first treating solution is sprayed. Selectively, the second nozzle member 480 may be provided in a bar shape, not an arc shape.

The controller 500 may control the spray unit 380. For example, the controller 500 may control spray position, spray point in time, and spray amount of the spray unit 380. For example, the controller 500 may control spray position, spray point in time, and spray amount of the first treating solution of the first nozzle member 400.

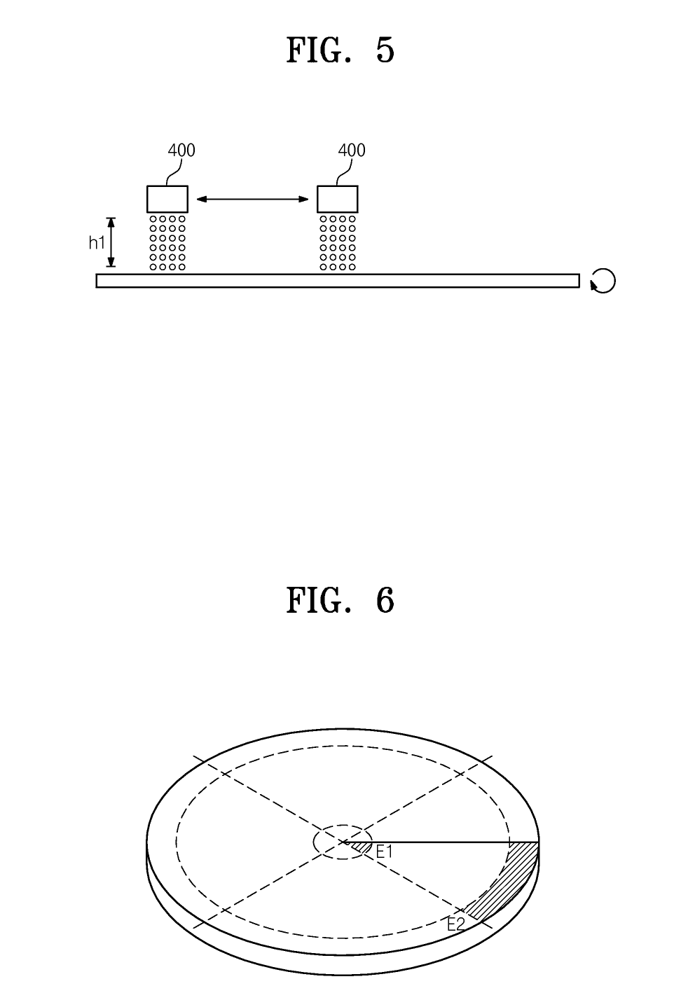

FIG. 5 is a diagram illustrating a conventional substrate cleaning method. FIG. 6 is a diagram illustrating a region where a first treating solution is supplied when the first treating solution is sprayed using the substrate cleaning method of FIG. 5. Referring to FIGS. 5 and 6, the conventional substrate treating apparatus may supply the first treating solution while the first nozzle member 400 reciprocates from an edge region of the substrate to the center region thereof. In this case, the first nozzle member 400 may move under the condition that a spray height at which the first treating solution is applied over a substrate using the first nozzle member 400 is maintained constantly. In this case, due to the same angular velocity, sizes of areas where the first treating solutions are supplied on the substrate during the same time may be different from each other. That is, when a treating solution is sprayed during the same time, a spray region E2 at the edge region of the substrate may be greater in size than a spray region E1 at the center of the substrate. For this reason, the amount of droplets colliding with the center of the substrate W per unit area may be greater than that colliding with the edge region thereof, and thus, the center region of the substrate W may be damaged.

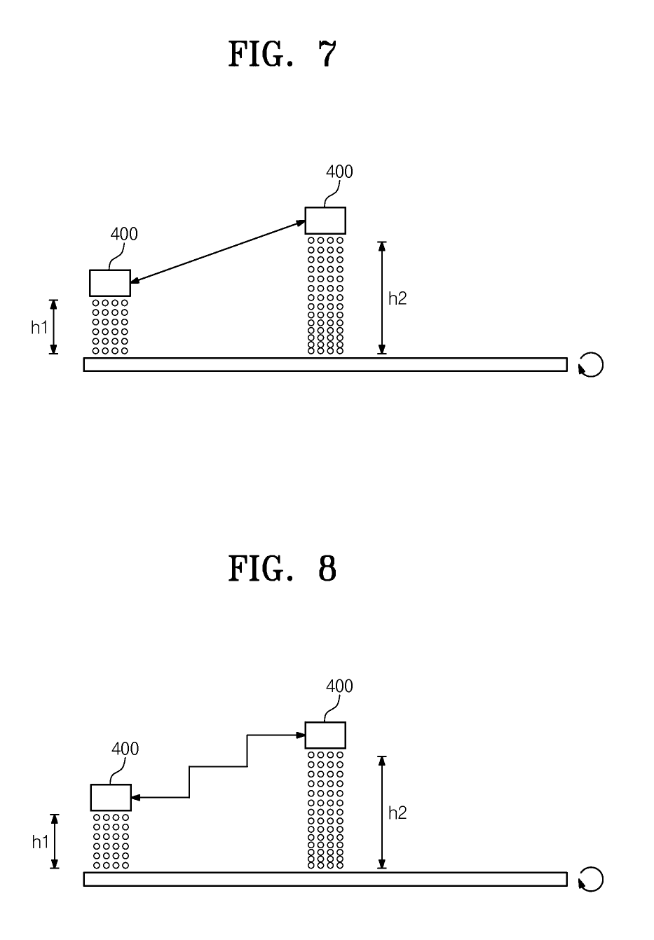

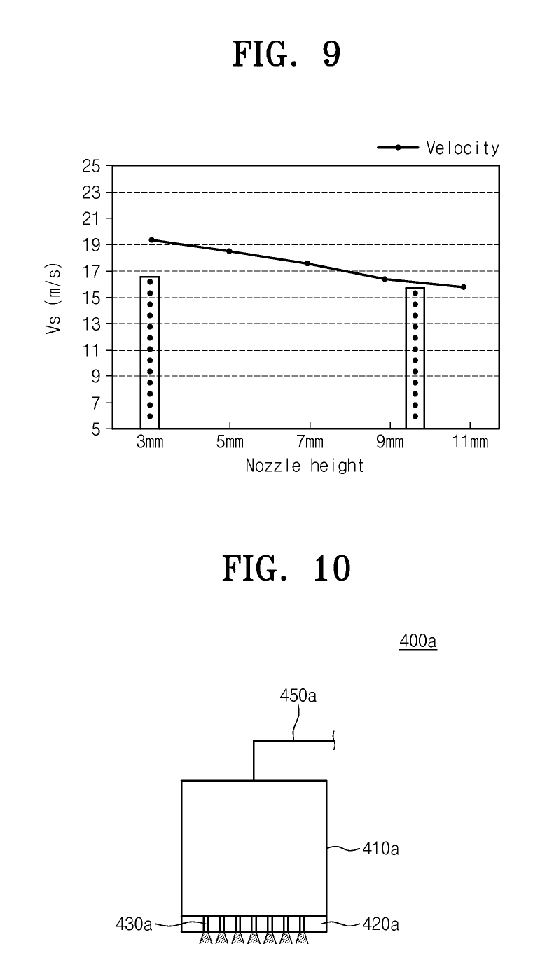

FIG. 7 is a diagram illustrating a substrate cleaning method for supplying the first treating solution on a substrate using the first nozzle member 400 according to an embodiment of the inventive concept. FIG. 8 is a diagram illustrating a substrate cleaning method for supplying the first treating solution on a substrate using the first nozzle member 400 according to another embodiment of the inventive concept. FIG. 9 is a diagram illustrating a surface velocity Vs at which the first treating solution reaches the substrate W, varied according to a spray height of the first nozzle member 400. Below, a substrate treating method will be described with reference to FIGS. 7 to 9. The controller 500 may spray the first treating solution while the first nozzle member 400 moves above the substrate W and between the edge region and the center region of the substrate. In this case, the controller 500 may differently adjust a first height h1 where the first nozzle member 400 sprays the first treating solution at the edge region of the substrate W and a second height h2 where the first nozzle member 400 sprays the first treating solution at the center of the substrate W. In this case, the second height h2 may be higher than the first height h1. The surface velocity Vs at which the first treating solution reaches the substrate W may be variable according to a discharge height at which the first nozzle member 400 discharges the first treating solution. That is, as the height of the first nozzle member 400 becomes higher, the velocity of droplets discharged may become slower due to air resistance, thereby reducing influence of the droplet on the substrate W. For example, a surface velocity Vs at which the first nozzle member 400 discharges a treating solution at a height of 10 mm may become slower by about 2.4 m/s than a surface velocity Vs at which the first nozzle member 400 discharges a treating solution at a height of 5 mm. Accordingly, since impact on the center region on the substrate W is reduced as much as about 12%, it may be possible to prevent the center region of the substrate W from being damaged. The controller 500 may adjust a height of the first nozzle member 400 such that a height of the first nozzle member 400 is continuously increased as the first nozzle member 400 moves from the edge region of the substrate W to the center region thereof. For example, the controller 500 may linearly increase the height of the first nozzle member 400. Selectively, The controller 500 may adjust a height of the first nozzle member 400 such that a height of the first nozzle member 400 is progressively increased as the first nozzle member 400 moves from the edge region of the substrate W to the center region thereof. For example, the controller 500 may stepwise increase the height of the first nozzle member 400.

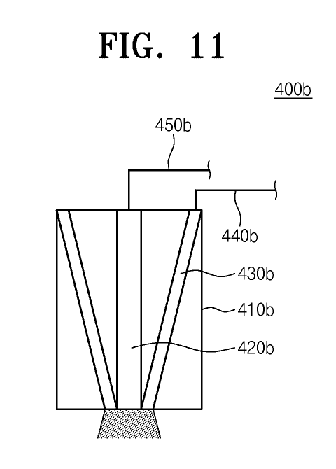

FIG. 10 is a diagram illustrating a first nozzle member 400a according to another embodiment of the inventive concept. FIG. 11 is a diagram illustrating a first nozzle member 400b according to another embodiment of the inventive concept. As illustrated in FIG. 10, the first nozzle member 400a may have micro-holes 430a in the body 410a. The first nozzle member 400a may pressurize the first treating solution sprayed via the micro-holes 430a to spray the first treating solution with mist. Furthermore, selectively, as illustrated in FIG. 11, the first nozzle member 400b may further include a gas supply unit 430b at a body 410b. The gas supply unit 430b may be provided to be inclined downwardly toward a first discharge hole 420b spraying the first treating solution. Accordingly, gas and the first treating solution may be sprayed respectively through the gas supply unit 430b and the first discharge hole 420b and may supply the first treating solution in a spray manner. In contrast, selectively, the first nozzle member may have another type of spray manner. Furthermore, selectively, the first nozzle member may supply the first treating solution in any other manners, not the spray manner.

The substrate treating apparatus described above may be used for various processes as well as the substrate cleaning process. For example, the substrate treating apparatus may be used for a substrate etching process. In addition, the substrate treating apparatus may include a rinse liquid member.

According to an exemplary embodiment of the inventive concept, it may be possible to improve cleaning efficiency.

The inventive concept, however, may be embodied in various different forms, and should not be construed as being limited only to the illustrated embodiments. Embodiments of the inventive concept are provided to illustrate more fully the scope of the inventive concept to those skilled in the art.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. A substrate treating apparatus comprising:
a housing defining a space for treating a substrate therein;
a spin head supporting and rotating the substrate in the housing;
a spray unit including a first nozzle member for spraying a first treating solution on the substrate placed on the spin head; and
a controller controlling the spray unit,
wherein the controller sprays the first treating solution while moving the first nozzle member between edge and center regions of the substrate and above the substrate, and
wherein the controller differently adjusts a first height at which the first treating solution is sprayed on the edge region of the substrate and a second height at which the first treating solution is sprayed on the center region of the substrate.

2. The substrate treating apparatus of claim 1, wherein the second height is higher than the first height.

3. The substrate treating apparatus of claim 2, wherein the controller controls the first nozzle member such that a height of the first nozzle member is progressively increased as the first nozzle member moves from the edge region of the substrate to the center region thereof.

4. The substrate treating apparatus of claim 2, wherein the controller controls the first nozzle member such that a height of the first nozzle member is continuously increased as the first nozzle member moves from the edge region of the substrate to the center region thereof.

5. The substrate treating apparatus of claim 3, wherein the first nozzle member comprises:
a body including an injection flow path and a first discharge hole therein, the first treating solution flowing through the injection flow path and the first discharge hole connected with the injection flow path and spraying the first treating solution on the substrate; and
a vibrator installed in the body and providing a vibration to the first treating solution flowing into the injection flow path.

6. The substrate treating apparatus of claim 3, wherein the first nozzle member comprises:
a body including an injection flow path and first micro-holes therein, the first treating solution flowing through the injection flow path and the first micro-holes connected with the injection flow path and spraying the first treating solution on the substrate.

7. The substrate treating apparatus of claim 3, wherein the first nozzle member comprises:
a body including an injection flow path and a first discharge hole therein, the first treating solution flowing through the injection flow path and the first discharge hole connected with the injection flow path and spraying the first treating solution on the substrate; and
a gas supply unit installed in the body and spraying a gas together with the first treating solution sprayed through the first discharge hole.

8. The substrate treating apparatus of claim 5, wherein the injection flow path comprises a first region and a second region each having a ring shape when viewed from the top, and
wherein a radius of the first region is greater than that of the second region.

9. The substrate treating apparatus of claim 8, wherein when viewed from the top, the first discharge holes of the first region are provided in a line along the first region, and the first discharge holes of the second region are provided in two lines along the second region.

10. A substrate treating apparatus comprising:
a housing defining a space for treating a substrate therein;
a spin head supporting and rotating the substrate in the housing;
a spray unit including a first nozzle member for spraying a first treating solution on the substrate placed on the spin head; and
a controller controlling the spray unit,
wherein the first nozzle member comprises:
a body including an injection flow path and a first discharge hole therein, the first treating solution flowing through the injection flow path and the first discharge hole connected with the injection flow path and spraying the first treating solution on the substrate; and
a vibrator installed in the body and providing a vibration to the first treating solution flowing into the injection flow path, and
wherein the controller sprays the first treating solution while moving the first nozzle member between edge and center regions of the substrate and above the substrate, and
wherein the controller differently adjusts a first height at which the first treating solution is sprayed on the edge region of the substrate and a second height at which the first treating solution is sprayed on the center region of the substrate.

11. The substrate treating apparatus of claim 10, wherein the second height is higher than the first height.

12. The substrate treating apparatus of claim 11, wherein the controller controls the first nozzle member such that a height of the first nozzle member is progressively increased as the first nozzle member moves from the edge region of the substrate to the center region thereof.

13. The substrate treating apparatus of claim 11, wherein the controller controls the first nozzle member such that a height of the first nozzle member is continuously increased as the first nozzle member moves from the edge region of the substrate to the center region thereof.

14. A method for cleaning a substrate using a first nozzle member spraying a first treating solution on the substrate, supported and rotated by a spin head, in a spray manner, the method comprising:
spraying the first treating solution while moving the first nozzle member between edge and center regions of the substrate and above the substrate,
wherein a first height at which the first treating solution is sprayed on the edge region of the substrate is different from a second height at which the first treating solution is sprayed on the center region of the substrate.

15. The method of claim 14, wherein the second height is higher than the first height.

16. The method of claim 15, wherein a height of the first nozzle member is progressively increased as the first nozzle member moves from the edge region of the substrate to the center region thereof.

17. The method of claim 15, wherein a height of the first nozzle member is continuously increased as the first nozzle member moves from the edge region of the substrate to the center region thereof.

18. The method of claim 16, wherein the first nozzle member comprises:
a body including an injection flow path and a first discharge hole therein, the first treating solution flowing through the injection flow path and the first discharge hole connected with the injection flow path and spraying the first treating solution on the substrate; and
a vibrator installed in the body and providing a vibration to the first treating solution flowing into the injection flow path.

19. The method of claim 16, wherein the first nozzle member comprises:
a body including an injection flow path and first micro-holes therein, the first treating solution flowing through the injection flow path and the first micro-holes connected with the injection flow path and spraying the first treating solution on the substrate.

20. The method of claim 16, wherein the first nozzle member comprises:
a body including an injection flow path and a first discharge hole therein, the first treating solution flowing through the injection flow path and the first discharge hole connected with the injection flow path and spraying the first treating solution on the substrate; and
a gas supply unit installed in the body and spraying a gas together with the first treating solution sprayed through the first discharge hole.
